(19) United States
(12) Patent Application Publication
(10) Pub. No.: US 2010/0127291 A1
(43) Pub. Date: May 27, 2010

(54) LIGHT EMITTING DIODE

(75) Inventor: Chia-Shou Chang, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: Foxconn Technology Co., Ltd., Tu-Cheng (TW)

(21) Appl. No.: 12/412,370

(22) Filed: Mar. 27, 2009

(30) Foreign Application Priority Data
Nov. 21, 2008 (CN) 200810305692.5

(51) Int. Cl. H01L 33/00

(52) U.S. Cl. 257/98; 257/100; 257/E33.06; 257/E33.061

(57) ABSTRACT

A light emitting diode includes a light emitting diode chip and first and second encapsulation units respectively of first and second encapsulating materials. The first encapsulation unit encapsulates the light emitting diode chip. The first encapsulation unit includes a light emitting surface defining a plurality of recesses therein and forming a plurality of first protrusions between the recesses. The first protrusions are alternately arranged with the recesses. The second encapsulation unit covers the light emitting surface of the first encapsulation unit. The second encapsulation unit includes a plurality of filling portions filling the recesses of the first encapsulation unit, respectively, and a plurality of second protrusions on the first protrusions, respectively.

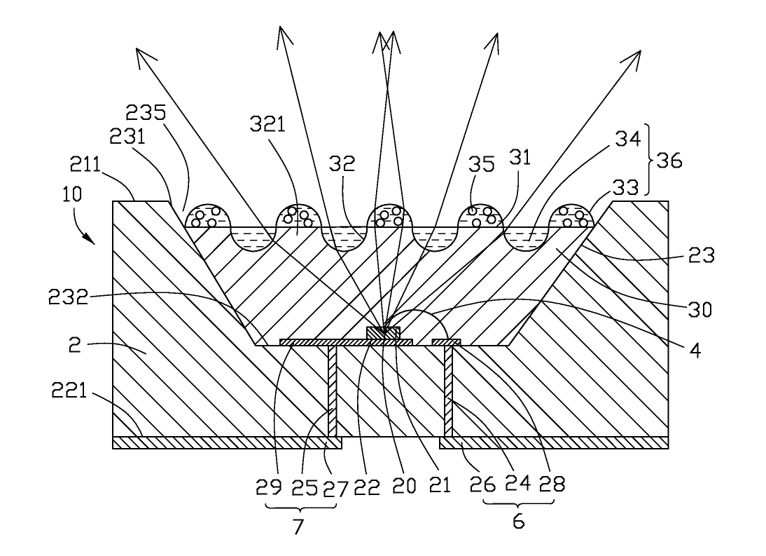

### BACKGROUND

1. Technical Field

The disclosure relates to light emitting diodes (LEDs), and more specifically to a light emitting diode (LED) having an improved encapsulation.

2. Description of Related Art

Presently, LEDs are preferred for use in non-emissive display devices than CCFLs (cold cathode fluorescent lamp) due to their high brightness, long lifespan, and wide color range.

A typical LED includes a base, an LED chip disposed on the base and an encapsulation encapsulating the LED chip. The encapsulation forms a flat light emitting surface on an outer surface thereof. The flat light emitting surface causes a total internal reflection of the light emitted from the LED chip, to thereby block the light from exiting through the light emitting surface. Therefore a light extraction efficiency of the LED is relatively low.

Therefore, an LED is desired to overcome the above described shortcomings.

### BRIEF DESCRIPTION OF THE DRAWINGS

The FIGURE is a cross-sectional view of an LED according to an exemplary embodiment.

### DETAILED DESCRIPTION OF THE EMBODIMENT

Referring to the FIGURE, a light emitting diode (LED) 10 includes an electrically insulating base 2, a first conductive member 6, a second conductive member 7, an LED chip 20, a first encapsulation unit 30 and a second encapsulation unit 36. The first and second conductive members 6, 7 are both electrically and thermally conductive.

The base 2 includes an upper surface 211 and a bottom surface 221 opposite to the upper surface 211. A receiving recess 23 is depressed from the upper surface 211 of the base 2. An opening 235 is thus defined through the upper surface 211 of the base 2 and communicates with the receiving recess 23. The receiving recess 23 is cup-shaped and converges downwardly along an axial direction of the LED 10. The receiving recess 23 has a depth less than a height of the base 2. Accordingly, the base 2 forms a mounting surface 232 at a bottom side of the receiving recess 23. The base 2 further forms a reflecting surface 231 surrounding the receiving recess 23 and between the opening 235 and the mounting surface 232. The reflecting surface 231 is tapered from the opening 235 towards the mounting surface 232. A layer of material with high light reflectivity, such as mercury, can be coated on the reflecting surface 231 of the base 2.

The LED chip 20 is received in the receiving recess 23 and mounted on the mounting surface 232 of the base 2. The LED chip 20 has a first electrode 21 and a second electrode 22 respectively formed on an upper surface and a bottom surface of the LED chip 20.

The first conductive member 6 is in electrical connection with the first electrode 21 of the LED chip 20 via a gold wire 4. The first conductive member 6 includes a first inner electrode 28, a first conductive pole 24 and a first outer electrode 26. The second conductive member 7 is directly connected to the second electrode 22 of the LED chip 20. The second conductive member 7 includes a second inner electrode 29 located under the LED chip 20 and is in electrical connection with the second electrode 22 of the LED chip 20, a second conductive pole 25 and a second outer electrode 27. The first inner electrode 28 and the second inner electrode 29 are formed on the mounting surface 232, and spaced from each other.

The first outer electrode 26 and the second outer electrode 27 are formed on the bottom surface 221 of the base 2, and spaced from each other. The first conductive pole 24 and the second conductive pole 25 extend through the base 2 from the mounting surface 232 to the bottom surface 221. The first conductive pole 24 and the second conductive pole 25 can be formed by filling electrically and thermally conductive material into through-holes pre-defined in the base 2. The first inner electrode 28 and the first outer electrode 26 are respectively located on two ends of the first conductive pole 24 and are electrically connected by the first conductive pole 24. The second inner electrode 29 and the second outer electrode 27 are respectively located on two ends of the second conductive pole 25 and are electrically connected by the second conductive pole 25.

A first encapsulation material is filled in the receiving recess 23 of the base 2 and forms the first encapsulation unit 30 which encapsulates the LED chip 20 on the base 2. The first encapsulation material includes light penetrable material, such as glass, epoxy, or resin. The first encapsulation unit 30 includes a light emitting surface 31 on a top thereof. The light emitting surface 31 defines a plurality of recesses 32 concaved downward, whereby a plurality of first protrusions 321 are formed between the recesses 32. The recesses 32 and the first protrusions 321 are alternately arranged.

The second encapsulation unit 36 is formed from a second encapsulation material. The second encapsulation material includes light penetrable material, such as glass, epoxy, or resin. The second encapsulation unit 36 includes a plurality of filling portions 34 and a plurality of second protrusions 33. The filling portions 34 correspond to the recesses 32 of the first encapsulation unit 30, respectively. Each of the filling portions 34 fills in a corresponding recess 32. The second protrusions 33 correspond to the first protrusions 321 of the first encapsulation unit 30, respectively. Each of the second protrusions 33 is located on a corresponding first protrusion 321. The second protrusions 33 include a wavelength conversion material 35 dispersed in the second encapsulation material. The wavelength conversion material 35, for example, is phosphor powder.

The first encapsulation material and the second encapsulation material further include particles, such as nano-particles or molecule particles, for adjusting a light refractive index thereof. The nano-particles are made of a material selected from one of titanium dioxide, tantalum dioxide and silicon dioxide. The molecule particles are made of phenol. The first encapsulation material has more particles than the second encapsulation material, whereby the first encapsulation material has a greater light refractive index than the second encapsulation material. The second encapsulation material has a greater light refractive index than air.

Since the light emitting surface 31 is uneven, when light emitted from the LED chip 20 reaches the light emitting surface 31, the reflection of the light back to the inside of the LED 10 at the light emitting surface 31 can be decreased or even avoided. This facilitates extraction of the light to the outside of the LED 10 and the light extraction efficiency of the LED 10 can be improved.

It will be obvious that, within the scope of the invention, many variations are possible to those skilled in the art. The scope of protection of the invention is not limited to the example given herein.

What is claimed is:

1. A light emitting diode comprising:
a light emitting diode chip;
a first encapsulation unit of a first encapsulating material, the first encapsulation unit encapsulating the light emitting diode chip, the first encapsulation unit comprising a light emitting surface, the light emitting surface defining a plurality of recesses and forming a plurality of first protrusions between the recesses, the first protrusions and the recesses being alternately arranged; and
a second encapsulation unit of a second encapsulating material, the second encapsulation unit covering the light emitting surface of the first encapsulation unit, the second encapsulation unit comprising a plurality of filling portions corresponding to the recesses of the first encapsulation unit and a plurality of second protrusions corresponding to the first protrusions, each of the filling portions being filled in a corresponding recess and each of the second protrusions being located on a corresponding first protrusion.

2. The light emitting diode as claimed in claim 1, wherein the second encapsulation unit has a smaller light refractive index than the first encapsulation unit.

3. The light emitting diode as claimed in claim 1, wherein each of the second protrusions of the second encapsulation unit comprises a wavelength conversion material therein.

4. The light emitting diode as claimed in claim 1, wherein the first and the second encapsulation units each comprise nano-particles therein.

5. The light emitting diode as claimed in claim 4, wherein the nano-particles are made of a material selected from one of the following materials: titanium dioxide, tantalum dioxide and silicon dioxide.

6. The light emitting diode as claimed in claim 1, wherein the first and the second encapsulation units each comprise a plurality of molecule particles.

7. The light emitting diode as claimed in claim 6, wherein the molecule particles are made of phenol.

8. The light emitting diode as claimed in claim 1, further comprising a base, the base defining a receiving recess receiving the light emitting diode chip and the first encapsulation unit therein.

9. A light emitting diode comprising:
a light emitting diode chip; and
an encapsulation unit of a first encapsulating material, the encapsulation unit encapsulating the light emitting diode chip, the encapsulation unit comprising a light emitting surface, the light emitting surface defining a plurality of recesses spaced from each other, a plurality of protrusions being provided between the recesses, the protrusions being alternately arranged with the recesses, the protrusions being made of a second encapsulating material, the recesses being filled with a same material as the second encapsulating material.

10. The light emitting diode as claimed in claim 9, wherein the second encapsulation material has a smaller light refractive index than the first encapsulation material.

11. The light emitting diode as claimed in claim 9, wherein each of the protrusions comprises a wavelength conversion material therein.

12. The light emitting diode as claimed in claim 11, wherein the wavelength conversion material is phosphor powder.

13. The light emitting diode as claimed in claim 9, wherein the first and the second encapsulation materials each comprise nano-particles therein.

14. The light emitting diode as claimed in claim 13, wherein the nano-particles are made of a material selected from one of titanium dioxide, tantalum dioxide and silicon dioxide.

15. The light emitting diode as claimed in claim 9, wherein the first and the second encapsulation materials each comprise a plurality of molecule particles therein.

16. The light emitting diode as claimed in claim 15, wherein the molecule particles are made of phenol.

17. The light emitting diode as claimed in claim 9 further comprising a base, the base defining a receiving recess receiving the light emitting diode chip and the encapsulation unit therein.
